(19) United States
(12) Patent Application Publication
(10) Pub. No.: US 2024/0145334 A1
(43) Pub. Date: May 2, 2024

(54) POWER MODULE WITH METALLIC HEAT SPREADER

(71) Applicant: Monolithic Power Systems, Inc., Kirkland, WA (US)

(72) Inventors: Fengchun He, Hangzhou (CN); Daocheng Huang, Santa Clara, CA (US); Junjie Feng, San Jose, CA (US); Xu Han, Hangzhou (CN)

(21) Appl. No.: 18/408,958

(22) Filed: Jan. 10, 2024

(51) Int. Cl. H01L 23/367; H05K 7/20

(52) U.S. Cl. CPC H01L 23/3675; H05K 7/209; H01L 25/16

(57) ABSTRACT

A power module has a substrate, a magnetic component disposed on the substrate, a plurality of power integrated circuits (ICs), and a heat spreader. The heat spreader and at least a part of the plurality of power ICs are disposed on a top surface of the substrate. The heat spreader is fixed on the substrate through a structural adhesive, covering top surfaces of the part of the plurality of power ICs on the top surface of the substrate, and is in contact with the top surfaces of the part of the plurality of power ICs on the top surface of the substrate through a thermal conductive adhesive. A difference between a height measured from a topmost surface of the magnetic component to the top surface of the substrate and a height measured from a topmost surface of the heat spreader to the top surface of the substrate is within 300 um.

### BACKGROUND OF THE INVENTION

### 1. Field of the Invention

The present invention generally relates to electronic components, and more particularly, relates to power modules.

### 2. Description of Related Art

Power modules are employed to provide one or more voltages to supply various electrical devices. A power module may integrate a magnetic component, a plurality of power integrated circuits (ICs), a plurality of driver ICs, and a plurality of passive devices, etc. Furthermore, to improve integration, the size of power modules needs to be smaller. In high power applications, larger current also put more challenges to thermal performance of the power module. Therefore, it is desirable to provide a cost-effective power module with high-power density, high-efficiency, excellent heat dissipation capability in space-constrained environments.

### SUMMARY OF THE INVENTION

It is an object of the present invention to provide a novel power module with enhanced thermal performance.

Embodiments of the present invention are directed to a power module, having a first substrate, a magnetic component, a primary side circuit, a secondary side circuit, and a plurality of passive devices. The magnetic component is disposed on the first substrate, and comprises a primary winding and a secondary winding. The primary side circuit comprises a first plurality of power integrated circuits (ICs), wherein the primary side circuit is coupled across the primary winding, and at least a part of the first plurality of power ICs are disposed on the top surface of the first substrate. The secondary side circuit comprises a second plurality of power ICs, wherein the secondary side circuit is coupled across the secondary winding, and at least a part of the second plurality of power ICs are disposed on the top surface of the first substrate. At least a part of the plurality of passive devices are disposed on the top surface of the first substrate. The heat spreader is disposed on the top surface of the first substrate, wherein the heat spreader covers the part of the first plurality of power ICs disposed on the top surface of the first substrate, the part of the second plurality of power ICs disposed on the top surface of the first substrate, and the part of the passive devices disposed on the top surface of the first substrate. The heat spreader is fixed on the first substrate through a structural adhesive, and is in contact with top surfaces of the part of the first plurality of power ICs disposed on the first surface of the first substrate and top surfaces of the part of the second plurality of power ICs disposed on the first surface of the first substrate through a thermal conductive adhesive.

Embodiments of the present invention are directed to a power module, having a substrate, a magnetic component disposed on the substrate, a plurality of power integrated circuits (ICs), and a heat spreader. The substrate has a top surface and a bottom surface. At least a part of the plurality of power ICs are disposed on the top surface of the substrate. The heat spreader is disposed on the top surface of the substrate, wherein the heat spreader covers top surfaces of the part of the plurality of power ICs disposed on the top surface of the substrate. The heat spreader is fixed on the substrate through a structural adhesive, and is in contact with the top surfaces of the part of the plurality of power ICs disposed on the top surface of the substrate through a thermal conductive adhesive. A difference between a height measured from a topmost surface of the magnetic component to the top surface of the substrate and a height measured from a topmost surface of the heat spreader to the top surface of the substrate is within 300 um.

Embodiments of the present invention are directed to an assembly method of a power module. The assembly method comprises disposing a magnetic component on a substrate, wherein the substrate comprises a top surface and a bottom surface, disposing a plurality of power integrated circuits (ICs) on the top surface of the substrate, mounting a heat spreader on the top surface of the substrate through a structural adhesive, and making the heat spreader in contact with top surfaces of the plurality of power ICs through a thermal conductive adhesive. The heat spreader covers the top surfaces of the plurality of power ICs. A difference between a height measured from a topmost surface of the magnetic component to the top surface of the substrate and a height measured from a topmost surface of the heat spreader to the top surface of the substrate is within 300 um.

These and other features of the present invention will be readily apparent to persons of ordinary skill in the art upon reading the entirety of this disclosure, which includes the accompanying drawings and claims.

### BRIEF DESCRIPTION OF DRAWINGS

The present invention can be further understood with reference to the following detailed description and the appended drawings, wherein like components are provided with like reference numerals. The drawings are only for illustration purpose, thus may only show part of the devices and are not necessarily drawn to scale.

FIG. 1A schematically shows a power module 100 in accordance with an embodiment of the present invention.

FIG. 1B schematically shows the power module 100 in accordance with another embodiment of the present invention.

FIG. 2A shows an explosive view of a power module 200A in accordance with an embodiment of the present invention.

FIG. 2B shows an explosive view of the power module 200B in accordance with another embodiment of the present invention.

FIG. 3 shows a three-dimensional view of the power module 200B in accordance with an embodiment of the present invention.

FIG. 4 shows a three-dimensional view of the heat spreader 201 in accordance with an embodiment of the present invention.

FIG. 5 shows a three-dimensional view of the heat spreader 201B in accordance with another embodiment of the present invention.

FIG. 6 shows a top view of the power module 200A in accordance with another embodiment of the present invention.

FIG. 7 shows a cross-sectional view of the power module 200A taken at a cross-section A-A shown in FIG. 6 in accordance with an embodiment of the present invention.

FIG. 8 shows a cross-sectional view of the power module 200A taken at a cross-section B-B shown in FIG. 6 in accordance with an embodiment of the present invention.

FIG. 9 shows a cross-sectional view of the power module 200A taken at a cross-section C-C shown in FIG. 6 in accordance with an embodiment of the present invention.

FIG. 10 illustrates an assembly method 400 of a power module.

### DETAILED DESCRIPTION OF THE INVENTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

The terms “left,” right,” “in,” “out,” “front,” “back,” “up,” “down, “top,” “atop”, “bottom,” “over,” “under,” “beneath,” “above,” “below” and the like in the description and the claims, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein.

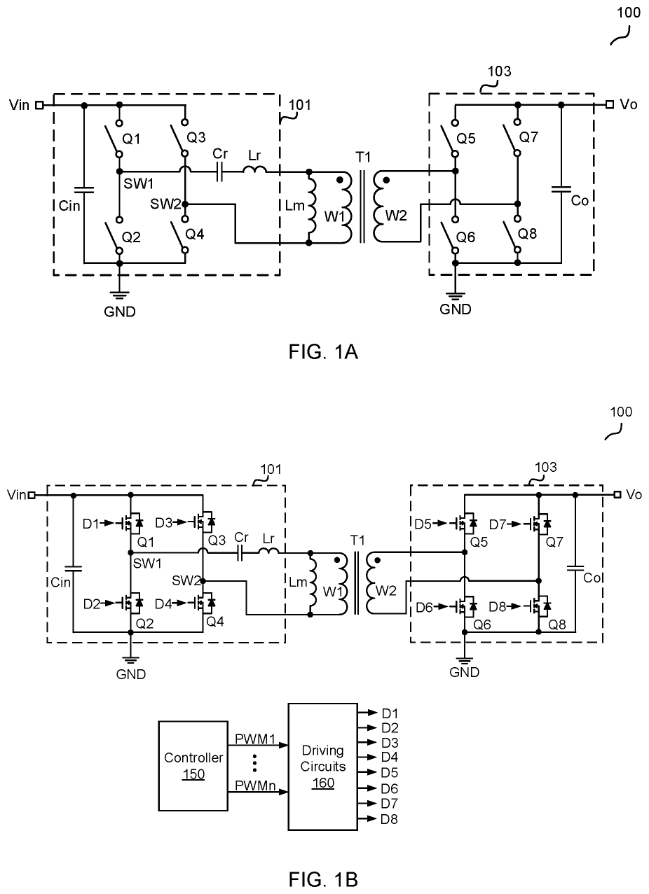

FIG. 1A schematically shows a power module 100 in accordance with an embodiment of the present invention. As shown in FIG. 1A, the circuit topology 100 comprises a primary side circuit 101, a transformer T1, and a secondary side circuit 103. The transformer T1 comprises at least one primary winding W1 and at least one secondary winding W2. In the example of FIG. 1A, the transformer T1 has one primary winding W1 on a primary side of the transformer T1 and one secondary winding W2 on a secondary side of the transformer T1. The primary side circuit 101 is coupled across the primary winding W1, and the secondary side circuit 103 is coupled across the secondary winding W2. One with ordinary skill in the art should understand that in other embodiments, the transformer T1 may also comprise more than one primary winding or secondary winding. In the example of FIG. 1A, the power module comprises an LLC resonant converter topology to receive an input voltage Vin by the primary side circuit 101 and provides an output voltage Vout by the secondary side circuit 103. The primary side circuit 101 comprises an input capacitor Cin, and further comprises four switches Q1, Q2, Q3, and Q4 to form a full-bridge switching circuit, and one with ordinary skill in the art should understand that a half-bridge switching circuit may also be employed in other embodiments of the present invention. The switches Q1 and Q2 are coupled in series between the input voltage Vin and a reference ground GND, and a switch node SW1 is formed by a common connection of the switches Q1 and Q2. Similarly, the switches Q3 and Q4 are coupled in series between the input voltage Vin and the reference ground GND, and a switch node SW2 is formed by a common connection of the switches Q3 and Q4.

In the example of FIG. 1A, the primary side circuit 101 further comprises a resonant capacitor Cr and a resonant inductor Lr. The resonant capacitor Cr, the resonant inductor Lr, and a magnetizing inductance Lm of the primary winding W1 are coupled in series between the switch nodes SW1 and SW2 to form a resonant tank circuit. In one embodiment, the resonant inductor Lr may also be a leakage inductance of the primary winding W1.

In the example of FIG. 1A, the secondary side circuit 103 comprises a rectifier circuit, and the rectifier circuit comprises switches Q5, Q6, Q7, and Q8. In the example of FIG. 1A, the rectifier circuit is a full-bridge rectifier circuit, and one with ordinary skill in the art should understand that any other rectifier circuit may also be employed without detracting merits of the present invention. The secondary side circuit 103 further comprises an output capacitor Co to filter a rectified signal provided by the rectifier circuit, and further provide an output voltage Vo and an output current to a load.

FIG. 1B schematically shows the power module 100 in accordance with another embodiment of the present invention. In the example of FIG. 1B, the switches Q1-Q8 are metal oxide semiconductor field transistors (MOSFETs), and the power module 100 further comprises a controller 150 and driving circuits 160 for the switches Q1-Q8. In the example of FIG. 1B, the controller 150 provides a plurality of control signals PWM1-PWMn to the driving circuits 160 to control the primary side circuit 101 and the secondary side circuit 103, and the driving circuits 160 provides driving voltages D1-D8 to drive the switches Q1-Q8 based on the control signals PWM. One with ordinary skill in the art should understand that the number of the plurality of control signals PWM1-PWMn is determined by the circuit topology and control scheme employed in the power module 100. E.g., in one embodiment, n=4, wherein the switches Q1 and Q4 of the primary side circuit 101 are turned ON and OFF synchronously, and the control signal PWM1 is employed to control the switches Q1 and Q4; the switches Q2 and Q3 of the primary side circuit 101 are turned ON and OFF synchronously, and the control signal PWM2 is employed to control the switches Q2 and Q3; the switches Q5 and Q8 of the secondary side circuit 103 are turned ON and OFF synchronously, and the control signal PWM3 is employed to control the switches Q5 and Q8; and the switches Q6 and Q7 of the secondary side circuit 103 are turned ON and OFF synchronously, and the control signal PWM4 is employed to control the switches Q7 and Q8.

The power module 100 with LLC resonant circuit topology is shown in FIG. 1A and FIG. 1B for example. One with ordinary skill in the art should appreciate that other topologies, like bridge topology, flyback topology, or feedforward topology, buck topology, boost topology, or buck-boost topology may also be adopted in a power module.

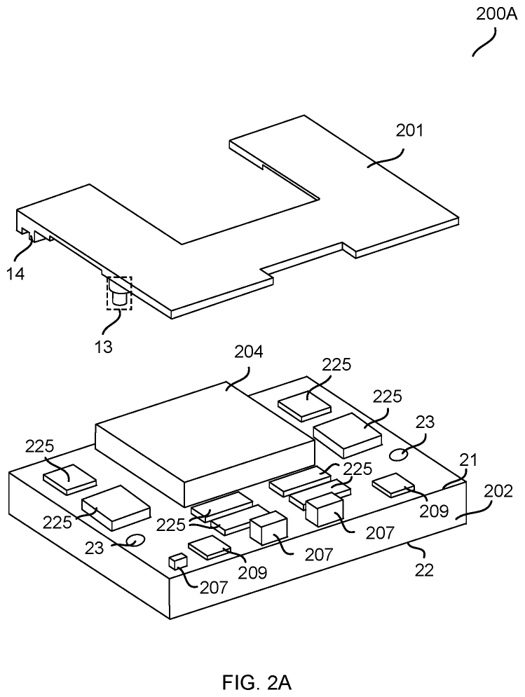

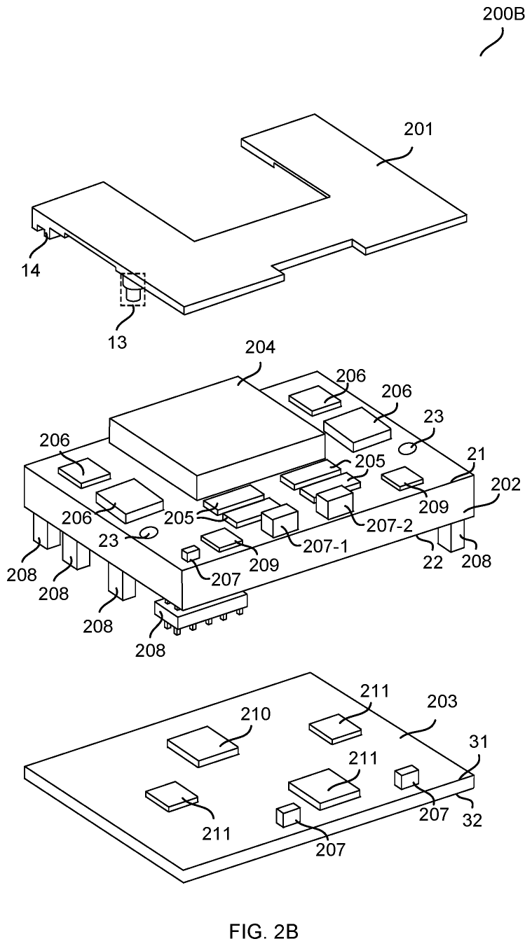

FIG. 2A shows an explosive view of a power module 200A in accordance with an embodiment of the present invention. As shown in FIG. 2A, the power module 200A comprises a heat spreader 201, a substrate 202, and a magnetic component 204 disposed on the substrate 202. The substrate 202 has a top surface 21 and a bottom surface 22, and the power module 200 further comprises a plurality of power integrated circuits (ICs) 225, and at least a part of the power ICs 225 are disposed on the top surface 21 of the substrate 202. In the embodiments of the present invention, the power ICs 225 are configured to deliver power from the input voltage Vin to the output voltage Vout. In one embodiment, the power ICs 225 may comprise power switches, e.g., MOSFETs, and in another embodiment, the power ICs 225 may comprise ICs integrating the power switches and driving circuits for the power switches. In one embodiment, the power module 200A further comprises a plurality of driver ICs 209 to drive the plurality of power ICs 225. In one embodiment, the power module 200A is a DC-DC converter employing the circuit topology shown in FIG. 1A or FIG. 1B, the primary side circuit 101 shown in FIG. 1A or FIG. 1B comprises a first part of the plurality of power ICs 225, and the secondary side circuit 103 shown in FIG. 1A or FIG. 1B comprises a second part of the plurality of power ICs 225. The components disposed on the top surface 21 of the substrate 202 usually have different heights, thus a topmost surface of the power module 200A may not be flat, which is inconvenient for installation of a heat sink. Furthermore, some of the heat generating components (e.g., the power ICs and the driver ICs) are disposed on the power module with a small size, which requires better heat dissipation for the power module 200A. To solve these problems, in the example of FIG. 2B, the heat spreader 201 is a metallic heat spreader which is disposed on the substrate 202 through a structural adhesive after assembly, and is in contact with top surfaces of the plurality of power ICs 225 disposed on the top surface 21 of the substrate 202 through a thermal conductive adhesive, thus the heat spreader 201 provides a flat topmost surface for installing an external heat sink. In some embodiments, the heat spreader 201 may be made of aluminum or copper. Compared to fixing heat spreaders by screws or other methods, using the structural adhesive to fix the heat spreader 201 saves space and reduces the size of the power module 200A. The combination of the heat spreader 201 and the thermal adhesive provides a better heat dissipation path for the main heat generating components (e.g., the power ICs 225), and thus enhancing the thermal performance of the power module 200A.

FIG. 2B shows an explosive view of the power module 200B in accordance with another embodiment of the present invention. In the example of FIG. 2B, similar to the power module 200A shown in FIG. 2A, the power module 200B comprises the heat spreader 201, the substrate 202, the magnetic component 204, and the plurality of driver ICs 209, and the power module 200B further comprises a substrate 203, a plurality of power ICs 205, and a plurality of power ICs 206. In one embodiment, the power module 200B is a DC-DC converter employing the circuit topology shown in FIG. 1A or FIG. 1B, i.e., the magnetic component 204 comprises the transformer T1 with the primary winding W1 and the secondary winding W2, and the power module 200B comprises the primary side circuit 101 and the secondary side circuit 103. In the example of FIG. 2B, the plurality of power ICs 205 and the plurality of power ICs 206 of the power module 200B forms the plurality of power ICs 225 shown in FIG. 2A. In one embodiment, the plurality of power ICs 205 are on the primary side of the transformer T1 to receive the input voltage Vin, e.g., the plurality of power ICs 205 forms the switches Q1-Q4 shown in FIG. 1A, i.e., the primary side circuit 101 comprises the plurality of power ICs 205. The plurality of power ICs 206 are on the secondary side of the transformer T1 to provide an output voltage Vout, e.g., the plurality of power ICs 206 forms the switches Q5-Q8 shown in FIG. 1A, i.e., the secondary side circuit 102 comprises the plurality of power ICs 206. In the example of FIG. 2B, at least a part of the plurality of power ICs 205 are disposed on the top surface 21 of the first substrate 202, and at least a part of the plurality of power ICs 206 are disposed on the top surface 22 of the first substrate 202.

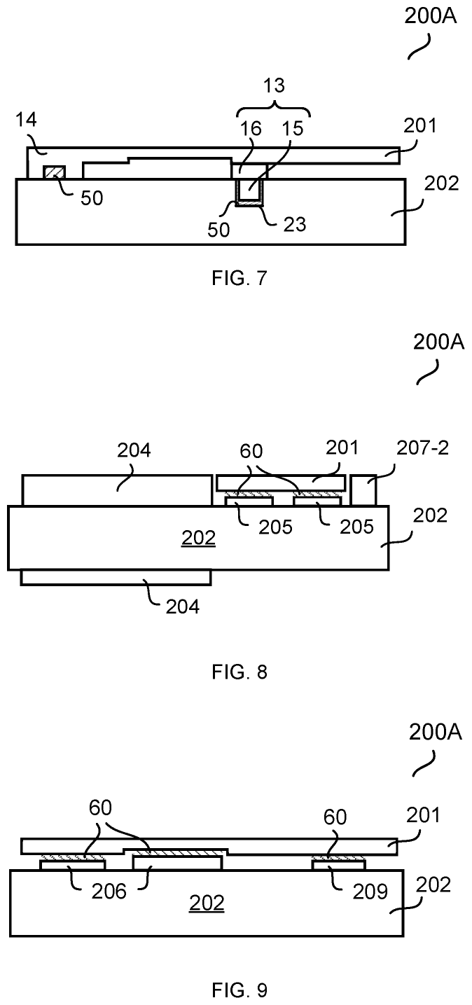

In the example of FIG. 2B, the substrate 202 further comprises at least two holes 23 on the top surface 21, and the heat spreader 201 comprises at least two assembly terminals 13 and at least two contact terminals 14. Each of the assembly terminals 13 are configured to assembly with the corresponding hole 23 to fix the heat spreader 201 onto the substrate 202 through the structural adhesive, and the at least two contact terminals 14 are configured to be connected with the substrate 202 through the structural adhesive to further fix the heat spreader 201, which will be further described in FIG. 7.

As shown in FIG. 2B, the substrate 203 has a top surface 31 facing the substrate 202 and a bottom surface 32 opposite to the top surface 31. In one embodiment, the substrates 202 and 203 are printed circuit boards (PCBs). As shown in FIG. 2B, the power module 200B further comprises a plurality of passive devices 207, and a plurality of connectors 208. In one embodiment, the plurality of passive devices 207 comprises the resonant capacitor Cr, the input capacitors Cin, the output capacitor Co, and other capacitors, resistors, and/or diodes of the power module 200. In another embodiment, the plurality of passive devices 207 further comprises the resonant inductor Lr. At least a part of the passive devices 207 are disposed on the top surface of the substrate 202. In the example of FIG. 2B, the plurality of passive devices 207 are disposed on both the top surface 21 and the bottom surface 22 of the substrate 202 and both the top surface 31 and the bottom surface 32 of the substrate 203. In the example of FIG. 2B, the passive devices 207-1 and 207-2 are not covered by the heat spreader 201 after assembly. In one embodiment, the passive devices 207-1 and 207-2 forms the input capacitor Cin in the circuit topology of FIG. 1A or FIG. 1B. In the example of FIG. 2B, the plurality of connectors 208 are disposed between the bottom surface 22 of the substrate 202 and the top surface 31 of the substrate 203. Each of the plurality of connectors 208 has a first end welded on the bottom surface 22 of the substrate 202 and a second end welded on the top surface 31 of the substrate 203 to connect the substrates 202 and 203 and transmit electrical signals between the substrates 202 and 203. In one embodiment, the connectors 208 comprises a plurality of metal pillars and at least one pin header.

In the example of FIG. 2B, at least a part of the plurality of driver ICs 209 are disposed on the top surface 21 of the substrate 202. In the example of FIG. 2B, the plurality of driver ICs 209 comprises the driving circuits 160 illustrated in FIG. 1B, i.e., the plurality of driver ICs 209 provide the driving voltages D1-D8 to the plurality of power ICs 205 and 206. In one embodiment, the power module 200 further comprises a controller IC 210, which may be disposed on the top surface 31 of the substrate 203. In the example of FIG. 2B, the controller 210 comprises the controller 150 illustrated in FIG. 1B, i.e., the controller IC 210 provides the control signals PWM1-PWMn to turn ON and OFF the plurality of power ICs 205 and 206. In the example of FIG. 2B, the controller 210 provides the control signals to the plurality of driver ICs 209, and the plurality of driver ICs 209 provide driving voltages D1-D8 to the plurality of power ICs 205 and 206 based on the control signals PWM provided by the controller 210. In another embodiment, driving circuits are integrated in the plurality of power ICs 205 and 206, and the controller 210 directly provides the control signals PWM to the plurality of power ICs 205 and 206. In one embodiment, the power module 200B further comprises at least one voltage converter ICs 211 to provide operation voltages for the controller IC 210 and the driver ICs 209. In the example of FIG. 2B, the bottom surface 32 of the substrate 203 has a plurality of pins (not seen in FIG. 2B) that connect nodes of the power module 200 to components that are external to the power module 200B.

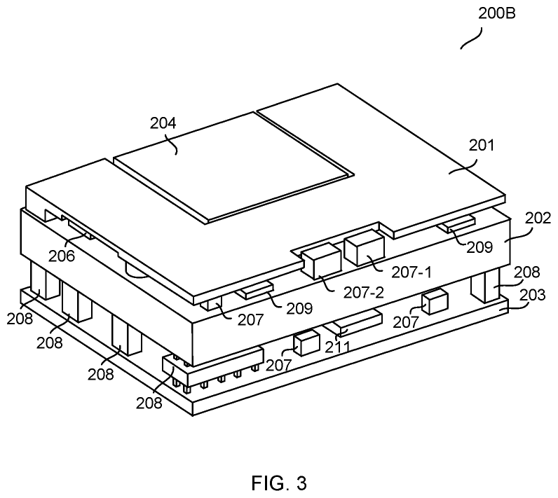

FIG. 3 shows a three-dimensional view of the power module 200B in accordance with an embodiment of the present invention. As shown in FIG. 3, the heat spreader 201 covers top surfaces of the power ICs 205 disposed on the top surface 21 of the substrate 202, top surfaces of the power ICs 206 disposed on the top surface 21 of the substrate 202, and top surfaces of at least a part of the passive devices 207 disposed on the top surface 21 of the substrate 202. In the example of FIG. 3, not all of the passive devices 207 disposed on the top surface 21 of the substrate 202 are covered by the heat spreader 201 (to be specific, the passive devices 207-1 and 207-2 are not covered by the heat spreader 201), and one with ordinary skill in the art should understand that the heat spreader 201 may also cover all of the passive devices 207 disposed on the top surface 21 of the substrate 202 in another embodiment. In the example of FIG. 3, the magnetic component 204 is placed beside the heat spreader 201, and is exposed on the substrate 202, e.g., the magnetic component 204 is not covered by the heat spreader 201.

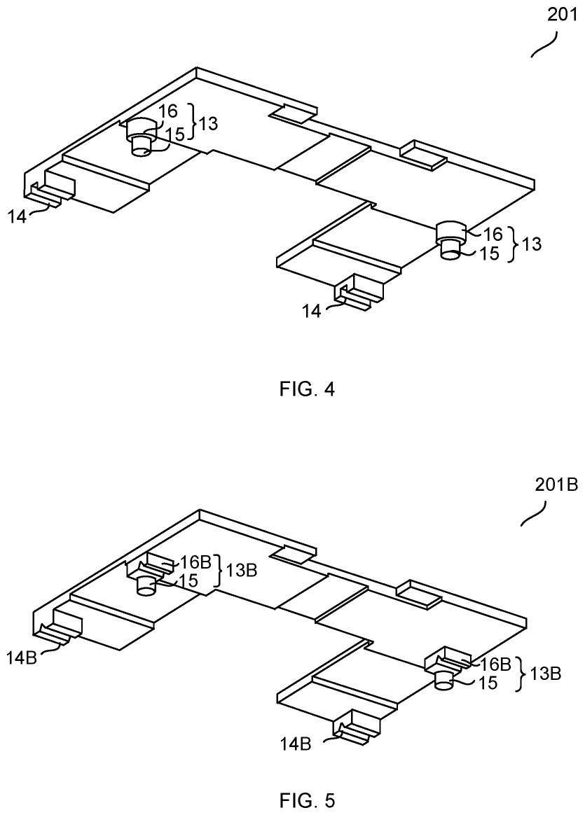

FIG. 4 shows a three-dimensional view of the heat spreader 201 in accordance with an embodiment of the present invention. In the example of FIG. 4, the heat spreader 201 has two assembly terminals 13 and two contact terminals 14. One with ordinary skill in the art should understand that the heat spreader 201 may also comprise more than two assembly terminals 13 or more than two contact terminals 14 in other embodiments. In the example of FIG. 4, each of the two assembly terminals 13 has an insertion portion 15 and an exposed portion 16 both in cylinder shapes, and during assembly, the insertion portions 15 are inserted into the corresponding holes 23 of the substrate 202. In the example of FIG. 4, each of the two contact terminals 14 has a cavity on its bottom surface, wherein the cavities are configured to be filled with the structural adhesive to connect the heat spreader 201 with the substrate 202 during assembly. In the example of FIG. 4, the cavities are in a cuboid shape.

FIG. 5 shows a three-dimensional view of the heat spreader 201B in accordance with another embodiment of the present invention. Similar to the heat spreader 201 shown in FIG. 4, the heat spreader 201B has two assembly terminals 13B and two contact terminals 14B. The contact terminals 14B of the heat spreader 201B are essentially same with the contact terminals 14 of the heat spreader 201 except that each of the contact terminals 14B has a cavity in a triangular prism shape. One with ordinary skill in the art should understand that the shapes of the cavities are not limited by the examples in FIG. 4 and FIG. 5, cavities with any other shapes may also be employed in other embodiments without detracting merits of the present invention. In the example of FIG. 5, each assembly terminal 13B has an insertion portion 15 and an exposed portion 16B, and each exposed portion 16B is in a cuboid shape. Each of the exposed portions 16B also has a cavity on its bottom surface to further fix the heat spreader 201B.

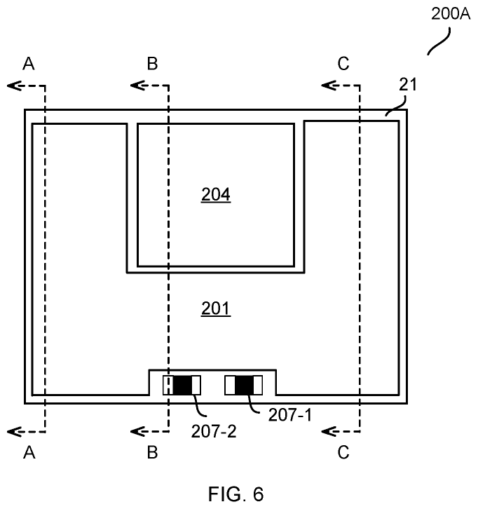

FIG. 6 shows a top view of the power module 200A in accordance with another embodiment of the present invention. As shown in FIG. 6, an orthographic projection of the heat spreader 201 on a plane of the top surface 21 of the substrate 202 falls within the top surface 21 of the substrate 202.

FIG. 7 shows a cross-sectional view of the power module 200A taken at a cross-section A-A shown in FIG. 6 in accordance with an embodiment of the present invention. To clearly illustrate the assembly between the heat spreader 201 and the substrate 202, FIG. 7 only shows the heat spreader 201 and the substrate 202, while the other components disposed on the substrate 202 are not shown in FIG. 7. As shown in FIG. 7, the insertion portion 15 of one of the assembly terminals 13 is inserted into the corresponding hole 23, and an outer surface of the insertion portion 15 is in contact with inner walls of the corresponding hole 23 through a structural adhesive 50, and in the example of FIG. 7, the inner wall of each hole 23 comprises a bottom wall and a side wall. In one embodiment, the holes 23, the insertion portions 15 and the exposed portions 16 are all cylindrical, wherein a diameter of each hole 23 is smaller than a diameter of the corresponding exposed portion 16, and is larger than a diameter of the corresponding insertion portion 15, and a depth of each hole 23 is larger than a height of the corresponding insertion portions 15, which forms a space between each hole 23 and the corresponding insertion portions 15. One with ordinary skill in the art should understand that the holes 23, the insertion portions 15 and the exposed portions 16 may also be other shapes. In one embodiment, during assembly, the structural adhesive 50 is first put in the at least two holes 23, e.g., the structural adhesive 50 is dispensed into the at least two holes 23 or coated on the inner walls of the at least two holes 23, and when each of the insertion portions 15 is inserted into the corresponding hole 23, the structural adhesive 50 is squeezed and thus fills the space between each insertion portion 15 and the corresponding hole 23 to fix the heat spreader 201 onto the substrate 202. Therefore, after assembly, the insertion portions 15 are inside the holes 23, and the exposed portions 16 are placed outside the holes 23, and are in contact with the top surface 21 of the substrate 202.

In the example of FIG. 7, the bottom side of each contact terminal 14 is in contact with the top surface 21 of the substrate 202, and the cavity of each contact terminal 14 is filled with the structural adhesive 50 to further fix the heat spreader 201.

FIG. 8 shows a cross-sectional view of the power module 200A taken at a cross-section B-B shown in FIG. 6 in accordance with an embodiment of the present invention. To clearly illustrate the assembly between the heat spreader 201 and the substrate 202, FIG. 8 only shows the heat spreader 201, the magnetic component 204, the passive device 207-2, the substrate 202, and a part of the plurality of power ICs 205 which are covered by the heat spreader 201, while the other components disposed on the substrate 202 are not shown in FIG. 8. As shown in FIG. 8, a topmost surface of the magnetic component 204 is above the top surface 21 of the substrate 202, and a difference between a height measured from the topmost surface of the magnetic component 204 to the top surface 21 of the substrate 202 and a height measured from a topmost surface of the heat spreader 201 to the top surface 21 of the substrate 202 is within 300 um, which is convenient for placing an external heat sink on top of the power module 200. As shown in FIG. 8, the heat spreader 201 is in contact with the top surfaces of the first plurality of power ICs 205 disposed on the top surface 21 of the substrate 202 through a thermal conductive adhesive 60.

FIG. 9 shows a cross-sectional view of the power module 200A taken at a cross-section C-C shown in FIG. 6 in accordance with an embodiment of the present invention. To clearly illustrate the assembly between the heat spreader 201 and the substrate 202, FIG. 9 only shows the heat spreader 201, the substrate 202, and a part of the plurality of power ICs 206 and one of the plurality of driver ICs 209 which are covered by the heat spreader 201, while the other components disposed on the substrate 202 are not shown in FIG. 9. As shown in FIG. 9, the heat spreader 201 is in contact with top surfaces of the second plurality of power ICs 206 and top surfaces of the driver ICs 209 disposed on the top surface 21 of the substrate 202 also through the thermal conductive adhesive 60. In one embodiment, the structural adhesive 50 comprises an epoxy resin adhesive, and the thermal conductive adhesive 60 comprises an adhesive with alumina particles. In the embodiments of the present invention, the structural adhesive 50 is configured to fix the heat spreader, and the thermal conductive adhesive 60 is configured to connect heat generating components (e.g., the plurality of power ICs 205 and 206, and the plurality of driver ICs 209) to the heat spreader 201. By using two types of adhesive (the structural adhesive 50 and the thermal conductive adhesive 60) to assemble the heat spreader 201 onto the power module 200, space occupied by assembling the heat spreader 201 is reduced, and the thermal performance of the power module 200 is also enhanced.

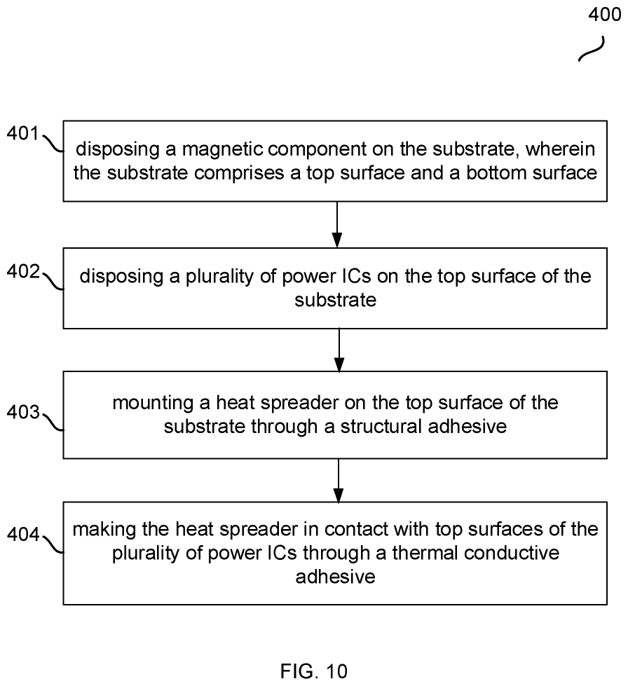

FIG. 10 illustrates an assembly method 400 of a power module. The assembly method 400 comprises steps 401-404.

In step 401, disposing a magnetic component on the substrate, wherein the substrate comprises a top surface and a bottom surface.

In step 402, disposing a plurality of power ICs on the top surface of the substrate.

In step 403, mounting a heat spreader on the top surface of the substrate through a structural adhesive.

In step 404, making the heat spreader in contact with top surfaces of the plurality of power ICs through a thermal conductive adhesive. In one embodiment, after assembly, the heat spreader covers the top surfaces of the plurality of power ICs, and a difference between a height measured from a topmost surface of the magnetic component to the top surface of the substrate and a height measured from a topmost surface of the heat spreader to the top surface of the substrate is within 300 um.

In one embodiment, each of the two assembly terminals comprises an insertion portion and an exposed portion, and mounting the heat spreader on the top surface of the substrate through the structural adhesive comprises putting the structural adhesive in at least two holes of the substrate, putting the thermal conductive adhesive on the top surfaces of the plurality of power ICs, squeezing the structural adhesive in the at least two holes by inserting the insertion portion of each assembly terminal into the corresponding hole to fill a space between the insertion portion of each assembly terminal and the corresponding hole with the structural adhesive, and placing the exposed portions of the at least two assembly terminals out of the at least two holes to make the exposed portions in contact with the top surface of the substrate.

In one embodiment, the assembly method further comprises connecting at least two contact terminals of the heat spreader with the top surface of the substrate through the structural adhesive.

In one embodiment, the structural adhesive comprises an epoxy resin adhesive, and the thermal conductive adhesive comprises an adhesive with alumina particles.

Note that in the heat spreader assembly method described above, the functions indicated in the boxes can also occur in a different order than those shown in FIG. 10. Fox example, two boxes presented one after another can actually be executed essentially at the same time, or sometimes in reverse order, depending on the specific functionality involved.

Obviously many modifications and variations of the present invention are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated and they obviously will be resorted to by those skilled in the art without departing from the spirit and the scope of the invention as hereinafter defined by the appended claims as only a preferred embodiment(s) thereof has been disclosed.

What is claimed is:

1. A power module, comprising:
a first substrate, having a top surface and a bottom surface;
a magnetic component disposed on the first substrate, wherein the magnetic component comprises a primary winding and a secondary winding;
a primary side circuit comprising a first plurality of power integrated circuits (ICs), wherein the primary side circuit is coupled across the primary winding, and wherein at least a part of the first plurality of power ICs are disposed on the top surface of the first substrate;
a secondary side circuit comprising a second plurality of power ICs, wherein the secondary side circuit is coupled across the secondary winding, and wherein at least a part of the second plurality of power ICs are disposed on the top surface of the first substrate; and
a heat spreader disposed on the top surface of the first substrate, wherein the heat spreader covers the part of the first plurality of power ICs disposed on the top surface of the first substrate, the part of the second plurality of power ICs disposed on the top surface of the first substrate, and the part of the passive devices disposed on the top surface of the first substrate; wherein
the heat spreader is fixed on the first substrate through a structural adhesive, and is in contact with top surfaces of the part of the first plurality of power ICs disposed on the first surface of the first substrate and top surfaces of the part of the second plurality of power ICs disposed on the first surface of the first substrate through a thermal conductive adhesive.

2. The power module of claim 1, wherein the magnetic component is exposed on the first substrate, and is placed beside the heat spreader, and wherein a difference between a height measured from a topmost surface of the magnetic component to the top surface of the first substrate and a height measured from a topmost surface of the heat spreader to the top surface of the first substrate is within 300 um.

3. The power module of claim 1, further comprising:
a plurality of driver ICs, configured to provide driving voltages to the first plurality of power ICs and the second plurality of power ICs, wherein at least a part of the plurality of driver ICs are disposed on the top surface of the first substrate, and the part of the plurality of driver ICs disposed on the top surface of the first substrate are covered by the heat spreader.

4. The power module of claim 1, further comprising:
a controller, configured to provide control signals to control the primary side circuit and the secondary side circuit.

5. The power module of claim 4, further comprising:
a second substrate having a top surface facing the first substrate and a bottom surface opposite to the top surface of the second substrate; and
a plurality of connectors disposed between the bottom surface of the first substrate and the top surface of the second substrate, wherein the plurality of connectors are configured to connect the first substrate and the second substrate and transmit electrical signals between the first substrates and the second substrate; wherein
the controller is disposed on the top surface of the second substrate.

6. The power module of claim 1, wherein:
the first substrate further comprises at least two holes, and the heat spreader comprises at least two assembly terminals, each of the assembly terminals comprising an insertion portion and an exposed portion; wherein
the insertion portion of each assembly terminal is inside the corresponding hole of the first substrate, and an outer surface of the insertion portion of each assembly terminal is in contact with inner walls of the corresponding hole through a structural adhesive; and wherein
the exposed portion of each assembly terminal is outside the corresponding hole of the first substrate, and is in contact with the top surface of the first substrate.

7. The power module of claim 6, wherein:
the heat spreader further comprises at least two contact terminals connected with the first substrate through the structural adhesive.

8. The power module of claim 1, wherein the structural adhesive comprises an epoxy resin adhesive, and the thermal conductive adhesive comprises an adhesive with alumina particles.

9. A power module, comprising:
a substrate, having a top surface and a bottom surface;
a magnetic component disposed on the substrate;
a plurality of power integrated circuits (ICs), wherein at least a part of the plurality of power ICs are disposed on the top surface of the substrate; and
a heat spreader disposed on the top surface of the substrate, wherein the heat spreader covers top surfaces of the part of the plurality of power ICs disposed on the top surface of the substrate; wherein
the heat spreader is fixed on the substrate through a structural adhesive, and is in contact with the top surfaces of the part of the plurality of power ICs disposed on the top surface of the substrate through a thermal conductive adhesive; and wherein
a difference between a height measured from a topmost surface of the magnetic component to the top surface of the substrate and a height measured from a topmost surface of the heat spreader to the top surface of the substrate is within 300 um.

10. The power module of claim 9, wherein:
the substrate further comprises at least two holes, and the heat spreader comprises at least two assembly terminals, each of the two assembly terminals comprising an insertion portion and an exposed portion; wherein
the insertion portion of each assembly terminal is inside the corresponding hole of the substrate, and an outer surface of the insertion portion of each assembly terminal is in contact with inner walls of the corresponding hole through a structural adhesive; and wherein
the exposed portion of each assembly terminal is outside the corresponding hole of the substrate, and is in contact with the top surface of the substrate.

11. The power module of claim 10, wherein:
the heat spreader further comprises at least two contact terminals connected with the substrate through the structural adhesive.

12. The power module of claim 9, wherein the structural adhesive comprises an epoxy resin adhesive, and the thermal conductive adhesive comprises an adhesive with alumina particles.

13. The power module of claim 9, wherein the substrate comprises a printed circuit board (PCB).

14. The power module of claim 9, wherein the plurality of power ICs comprises a plurality of metal oxide semiconductor field transistors (MOSFETs).

15. The power module of claim 9, wherein the magnetic component comprises a primary winding and a secondary winding, the power module further comprising:
a primary side circuit to receive an input voltage, comprising a first part of the plurality of power ICs, wherein the primary side circuit is coupled across the primary winding; and
a secondary side circuit to provide an output voltage, comprising a second part of the plurality of power ICs, wherein the secondary side circuit is coupled across the secondary winding.

16. An assembly method of a power module, comprising:
disposing a magnetic component on a substrate, wherein the substrate comprises a top surface and a bottom surface;
disposing a plurality of power ICs on the top surface of the substrate;
mounting a heat spreader on the top surface of the substrate through a structural adhesive; and
making the heat spreader in contact with top surfaces of the plurality of power ICs through a thermal conductive adhesive; wherein
the heat spreader covers the top surfaces of the plurality of power ICs; and wherein
a difference between a height measured from a topmost surface of the magnetic component to the top surface of the substrate and a height measured from a topmost surface of the heat spreader to the top surface of the substrate is within 300 um.

17. The assembly method of claim 16, wherein the heat spreader comprises at least two assembly terminals, each of the two assembly terminals comprising an insertion portion and an exposed portion, and wherein mounting the heat spreader on the top surface of the substrate through the structural adhesive comprises:
putting the structural adhesive in at least two holes of the substrate;
putting the thermal conductive adhesive on the top surfaces of the plurality of power ICs;
squeezing the structural adhesive in the at least two holes by inserting the insertion portion of each assembly terminal into the corresponding hole to fill a space between the insertion portion of each assembly terminal and the corresponding hole with the structural adhesive; and
placing the exposed portions of the at least two assembly terminals out of the at least two holes to make the exposed portions in contact with the top surface of the substrate.

18. The assembly method of claim 17, further comprising:
connecting at least two contact terminals of the heat spreader with the top surface of the substrate through the structural adhesive.

19. The assembly method of claim 16, wherein the structural adhesive comprises an epoxy resin adhesive, and the thermal conductive adhesive comprises an adhesive with alumina particles.
